(19) United States
(12) Patent Application Publication
(10) Pub. No.: US 2010/0097069 A1
(43) Pub. Date: Apr. 22, 2010

(54) EVALUATION SYSTEM, LIGHTING DEVICE, AND IMAGE DISPLAY DEVICE

(76) Inventors: Jun Sakaguchi, Osaka (JP); Hiroki Ogawa, Osaka (JP); Yoshiki Kitahara, Osaka (JP); Katsuhiro Ono, Osaka (JP); Kiyoshi Takahashi, Kyoto (JP); Minoru Ozasa, Kyoto (JP)

Correspondence Address: SNELL & WILMER L.L.P. (Panasonic), 600 ANTON BOULEVARD, SUITE 1400, COSTA MESA, CA, 92626, US

(21) Appl. No.: 12/443,174

(22) PCT Filed: Oct. 2, 2007
(86) PCT No.: PCT/JP2007/069302

§ 371 Date: Mar. 26, 2009

(30) Foreign Application Priority Data
Oct. 3, 2006 (JP) 2006-272110
May 15, 2007 (JP) 2007-129879

(51) Int. Cl. G01R 31/00

(52) U.S. Cl. 324/403

(57) ABSTRACT

An image display device accurately evaluates the possibility of problems occurring due to the state of impure gas inside a discharge envelope in a high pressure discharge lamp. The image display device includes the high voltage discharge lamp and an evaluation unit (51) for evaluating the possibility of problems occurring due to the state of impure gas. The evaluation unit (51) includes a high voltage pulse generator (57) that generates a high voltage pulse for breaking insulation in the high pressure lamp, a constant current generator (58) that generates a constant current for illuminating the high pressure discharge lamp in a glow discharge state, a lamp voltage measurer (59) that measures lamp voltage during illumination in the glow discharge state, an LED (63), and a controller (65). When the lamp voltage measured by the lamp voltage measurer (59) is a predetermined value or higher, the controller (65) judges that the possibility of problems occurring in the high pressure lamp is high, and lights the LED (63).

### TECHNICAL FIELD

The present invention relates to an evaluation system, an illumination device, and an image display device.

### BACKGROUND ART

High pressure discharge lamps are used as light sources in image display devices such as liquid crystal projectors. This kind of high pressure discharge lamp (hereinafter simply referred to as a lamp) is a so-called high pressure mercury lamp that has a discharge envelop in which a pair of electrodes are provided and is filled with mercury as light emitting matter and noble gas such as argon.

The discharge envelope of a high pressure mercury lamp is highly prone to blackening. In order to prevent blackening, halogen for a halogen cycle is also enclosed in the discharge envelope. This blackening of the discharge envelop starts to occur in areas around the electrodes at approximately 100 hours of lighting ageing time. When the blackening further advances due to subsequent lighting ageing, attenuation of the luminous flux of the lamp occurs, as well as swelling and loss of transparency occurring due to the temperature becoming abnormally high in the blackened parts of the discharge envelope. This leads to breakage of the discharge envelope.

It is thought that the cause of the blackening is a reduction in the halogen cycle function due to molecular gas (such molecular gas may be impure gas caused by lamp lighting) such as hydrogen, fluid or the like that remains in the discharge envelope, in other words, the discharge space.

One way that has been developed to reducing impurities and the like in the discharge space is to use highly pure quartz that contains no more than 5 (ppm) of OH radicals as the material of the discharge envelope, and to use a highly pure material containing a reduced amount of accessory composition such as potassium (K) as the material of the electrodes (tungsten) (see Patent Document 1).

In the manufacturing process of the discharge envelope, the quartz envelope is subjected to vacuum high-temperature heating in order to remove water (H₂O) and the like impregnated (remaining) inside the quartz envelope as a result of the quartz envelop being heated on a gas burner during processes including the process for forming the quartz envelope. The quartz envelope is therefore subjected to vacuum high-temperature heating in order to remove the water and the like after such processes. The electrodes are also first subjected to hydrogen reduction processing, vacuum high-temperature processing and the like to degas before sealing the discharge envelope, and then subjected to a high-purification process such as argon gas reflux, in order to prevent oxidation of the electrodes that is caused by heating by a gas burner in the electrode sealing process.

Patent Document 1: Japanese Unexamined Application Publication No. S54-131368

### DISCLOSURE OF THE INVENTION

### Problem to be Solved by the Invention

Even in a high pressure mercury lamp in which the described measures are taken, problems such as blackening of the discharge envelope may occur when the lamp is actually used. In other words, there are still impurities in the discharge space.

However, a technique is yet to be established for accurately and easily evaluating (investigating) the state of existence of impurities in the discharge space, particularly molecular gas (impure gas) during illumination. For this reason, although small in number, lamps in which blackening is highly likely to occur do appear on the market.

Note that the stated problem also occurs in low pressure mercury lamps such as cold cathode fluorescent lamps and hot cathode fluorescent lamps in which mercury is sealed as ultraviolet ray (ultraviolet rays of 254 nm, for instance) emitting matter after washing and drying the glass tube that is the discharge envelope, or after applying and drying a suspension for forming a phosphor layer to the inner surface of the glass tube.

The present invention was conceived in view of the stated problem, and has an object of providing an evaluation system and the like capable of easily and accurately evaluating a state of existence of molecular gas that may cause problems in a discharge lamp.

### Means for Solving the Problem

An evaluation system of the present invention an evaluation system for evaluating a state of existence of molecular gas in a discharge space in a discharge lamp, the evaluation system including: an illumination unit operable to cause the discharge lamp to illuminate in a normal glow discharge state; a voltage measuring unit operable to measure lamp voltage of the discharge lamp illuminated in the normal glow discharge state; an evaluation unit operable to make an evaluation that the measured lamp voltage exceeds a pre-set reference voltage by a certain value or greater; and an output unit operable to output a result of the evaluation.

Here, “molecular gas” refers to gas having molecularity, such as hydrogen or water (water vapor), and a “state of existence of molecular gas” refers to a state of the existence of gas defined by the amount (absolute amount) of the molecular gas.

Furthermore, the “output unit” may be anything that enables an evaluation result to be output, examples of the output unit being a lamp, an LED or the like, or a speaker that generates a sound.

Furthermore, “discharge lamp” includes the concepts of a high pressure discharge lamp having mercury as a light emitting matter, and a low pressure discharge lamp (including a cold cathode fluorescent lamp and a hot cathode fluorescent lamp) having mercury as an ultraviolet light emitting matter.

Meanwhile, a “normal glow discharge state” denotes discharge in a state in glow discharge when discharge voltage is substantially constant even if current is increased.

Furthermore, the discharge lamp may be a high pressure discharge lamp, and mercury, halogen and argon may be contained in the discharge space, the illumination unit may cause the high pressure discharge lamp to illuminate in the normal glow discharge using a lamp current that is a direct current, the pre-set reference voltage may be an initial lamp voltage value, and the certain value may be 90 V. Alternatively, the discharge lamp may be a high pressure discharge lamp, and mercury, halogen and argon may be contained in the discharge space, the illumination unit may cause the high pressure discharge lamp to illuminate in the normal glow discharge using a lamp current that is an alternating current, the pre-set reference voltage may be an initial lamp voltage value, and the certain value may be 60 V.

Here, “initial lamp voltage value” refers to a lamp voltage in glow discharge in an initial lighting of the lamp after the lamp is completed.

An illumination device of the present invention is an illumination device for illuminating a discharge lamp in which a pair of electrodes are provided in a discharge envelope and mercury is contained in a discharge space, the mercury being a light emitting matter or an ultraviolet light emitting matter, the illumination device including: an evaluation unit operable to evaluate a state of existence of molecular gas in a discharge space in a discharge lamp, wherein the evaluation unit is the described evaluation system.

An image display device of the present invention is an image display device including a discharge lamp in which a pair of electrodes are provided in a discharge envelope and mercury is contained in a discharge space, the mercury being a light emitting matter or an ultraviolet light emitting matter, the image display device including: an evaluation unit operable to evaluate a state of existence of molecular gas in a discharge space in a discharge lamp, wherein the evaluation unit is the described evaluation system.

### ADVANTAGEOUS EFFECTS

The evaluation system of the present invention measures lamp voltage in a normal glow state, and uses the measured lamp voltage value to make an evaluation. Having carried out various investigations, the inventors determined that when the lamp voltage reaches or exceeds a predetermined value (a value that is a certain value higher than a reference value), molecular gas remains in the discharge space, thus increasing the possibility of a problem occurring. Therefore, in the evaluation system of the present invention, when the lamp voltage reaches or exceeds a predetermined value, an evaluation result to that effect is output. This enables the state of existence of molecular gas of the discharge lamp to be known.

Furthermore, a discharge lamp for which such an evaluation has been output has a high possibility of a problem such as blackening occurring, and therefore can be specified as a discharge lamp having a possibility of lamp luminous flux attenuating or the discharge envelope breaking.

Furthermore, if the predetermined value is known, the possibility of blackening occurring in the lamp can be evaluated on the basis of the result of measuring the lamp voltage in the normal glow discharge state.

Since the illumination device of the present invention includes the above-described evaluation system, the result of the evaluation of the state of existence of molecular gas in the lamp can be displayed if the lamp voltage is a predetermined value of higher. In particular, when the lamp voltage becomes a predetermined value or higher, there is a high possibility that the discharge lamp will become defective or malfunction. A discharge lamp in which there is a danger of lamp luminous flux attenuating or the discharge envelope breaking can be specified.

The image display device of the present invention includes the described evaluation system, and therefore the result of measuring the evaluation of the state of existence of molecular gas in the lamp can be displayed if the lamp voltage is a predetermined value of higher. In particular, when the lamp voltage becomes a predetermined value or higher, there is a high possibility that the discharge lamp will become defective or malfunction. A discharge lamp in which there is a danger of lamp luminous flux attenuating or the discharge envelope breaking can be specified.

### BRIEF DESCRIPTION OF THE DRAWINGS

FIG. 1 is a longitudinal cross-sectional view of a lamp of a first embodiment;

FIG. 2 is a conceptual drawing of an evaluation system;

FIG. 3 is a block diagram of an evaluation unit of the embodiment;

FIG. 4 is a flowchart pertaining to a controller;

FIG. 5 shows distribution of lamp voltage in glow discharge;

FIG. 6 is a perspective diagram of a projector of a second embodiment, with part of the projector cut away;

FIG. 7 is a block diagram of an illumination unit;

FIG. 8 is a flowchart pertaining to the controller;

FIG. 9 is a waveform diagram of lamp voltage and lamp current from when voltage starts to be applied to the lamp through to when arc discharge starts;

FIG. 10 is a vertical cross sectional view of a lamp unit of the second embodiment;

FIG. 11 is a block diagram of an illumination unit that is an example of a modification to the second embodiment;

FIG. 12 is a circuit diagram of a detection-use voltage generator;

FIG. 13 is a flowchart pertaining to a controller of the illumination unit that is an example of a modification of the second embodiment; and

FIG. 14 is an overall perspective view of aback panel projection type image display device.

### DESCRIPTION OF NUMERICAL REFERENCES

1 Lamp
5 Discharge envelope
15, 17 Electrode portion (electrode)
35 Mercury
51 Evaluation unit
57 High voltage pulse generator
58 Constant current generator
59 Lamp voltage measurer
61 Clock part
63 Display part (LED)
101 Projector
103 Lamp unit
115 Evaluation unit

### BEST MODE FOR CARRYING OUT THE INVENTION

### First Embodiment

With reference to the drawings, the following describes a high pressure mercury discharge lamp (hereinafter simply referred to as a lamp) which is one type of high pressure discharge lamp, and an evaluation system for the lamp, as a first embodiment of the present invention.

1. Lamp

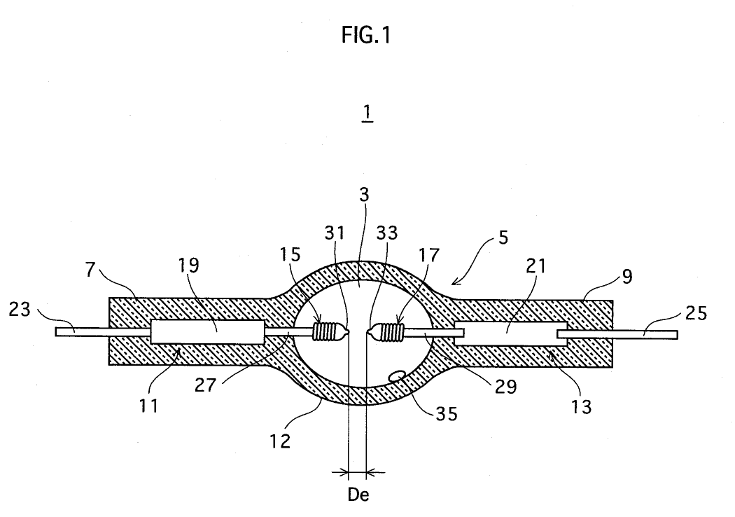

FIG. 1 is a longitudinal cross-sectional view of the lamp of the first embodiment.

As shown in FIG. 1, the lamp 1 is composed of a discharge envelope 5 which has an internal discharge space 3, and electrode structures 11 and 13 that are sealed through sealing portions 7 and 9 such that a tip of the electrode structures 11 and a tip of the electrode structure 13 oppose each other in the discharge space 3 (the tips are electrode portions described later).

The discharge envelope 5 is composed of a light emitting portion 12 and sealing portions 7 and 9. The light emitting portion 12 is located in substantially the center of the discharge envelope 5 and is substantially spheroid-shaped. The sealing portions 7 and 9 are provided on either side of the light emitting portion 12. The discharge space 3 is in the light emitting portion 12.

The electrode structures 11 and 13 are composed of electrode portions 15 and 17, metal foils 19 and 21, and external lead wires 23 and 25 connected (e.g., welded together) in the stated order. Here, a tip portion of the electrode structure 11 and a tip portion of the electrode structure 13 are electrode portions 15 and 17, respectively (each tip portion being an “electrode” in the present invention).

The external lead wires 23 and 25 extend outside through the sealing portions 7 and 9, at end faces of the sealing portions 7 and 9 at the opposite side of each of the sealing portions 7 and 9 to the light emitting portion 12.

The electrode portions 15 and 17 are disposed so as to oppose each other on a substantially straight line in the discharge space 3, and are composed of electrode rods 27 and 29, and electrode coils 31 and 33 provided on the tips of the electrode rods 27 and 29.

The electrode structures 11 and 13 are sealed at the sealing portions 7 and 9 mainly by the metal foils 19 and 21, such that a distance De between the electrode coils 31 and 32 is a predetermined length. As a result, the discharge space 3 is formed in an airtight state inside the light emitting portion 12. In this state in which the electrode structures 11 and 13 are sealed at the sealing portions 7 and 9, the electrode portions 15 and 17 extend from the sealing portions 7 and 9 into the discharge space 3 as shown in FIG. 1.

Sealed in the discharge space 3 is mercury 35 as light emitting matter, noble gas for startup assistance, and halogen for a halogen cycle.

A specific example of the lamp 1 is now described. Note that the specific example given here is simply one example, and the present invention is not limited to this example.

The discharge envelope 5 is made of quartz glass. With the electrode structures 11 and 13 disposed at predetermined positions in the discharge envelop 5 (the electrode coils 31 and 33 in predetermined positions in the discharge space 3), the sealing portions 7 and 9 are hermetically sealed via the metal foils 19 and 21 using a so-called shrink method.

A molybdenum material is used for the electrode structures 11 and 13, in other words, the electrode coils 31 and 33, the electrode rods 27 and 29, the metal foils 19 and 21, and the external lead wires 23 and 25. Note that another material, such as a tungsten material, may be used instead of the molybdenum material.

Argon is used as the noble gas inserted in the discharge space 3. Bromine (Br) is used as the halogen (gas). More specifically, methylene bromine (CH₂Br₂) is used, and sealed in the discharge space 3 mixed with argon.

An implementation example in which the described structure is specifically applied to a lamp input power of 120 (W) is now described.

The dimensions of the discharge envelope 5 are as follows. The overall length is 60 (mm). The outer diameter of a central portion of the light emitting unit 12 (i.e., the portion having the greatest outer diameter) is 9.4 (mm), and the inner diameter is 4.2 (mm). The overall length of the light emitting portion 12 is 7.3 (mm). The distance De between tips of the electrodes (i.e., the electrode coils 31 and 33) in the discharge space 3 is 1.0 (mm), with the lamp 1 being a so-called short arc type. The wall loading is set at 1.5 (W/mm²).

The mercury 35 in the discharge space 3 is enclosed at approximately 0.20 (mg) per unit of capacity (mm³) (equivalent to approximately 20 (MPa)) at the vapor pressure in the discharge space 3 during normal illumination). The argon that is the noble gas is enclosed so as to be approximately 30 (kPa) at the vapor pressure in the discharge space 3 during normal illumination. The bromide that is the halogen is enclosed at approximately 1.3×10⁻⁴ (μmol) per unit of capacity (mm³).

After startup, the lamp 1 transitions from a regular glow discharge state (hereinafter simply referred to as a glow discharge state) to an arc discharge state, and in normal illumination (i.e., in the arc discharge state), the lamp 1 illuminates with a lamp input power of 120 (W) and a lamp current of approximately 1.7 (A).

Note that the lamp 1 is subjected to 4 hours of ageing in an arc discharge state in so-called hot cathode operation. The ageing is performed after manufacturing, under conditions of a lamp input power of 120 (W) with an alternating wave (square wave) of an illumination frequency of 166 (Hz) by a purpose-specific illumination unit, and includes a blinking cycle.

2. Evaluation System

The evaluation system is for evaluating the state of existence of impure gas (molecular gas) in the discharge envelope 5 of the lamp 1 have the stated structure (also referred to simply as an impure gas state).

The evaluation system performs evaluation by, after insulation breakdown of the lamp 1, performing constant current control to cause the lamp 1 to illuminate, measuring the lamp voltage Vla applied to the lamp during illumination, and evaluating the state of existence of impure gas in the discharge space according to the result of the measuring.

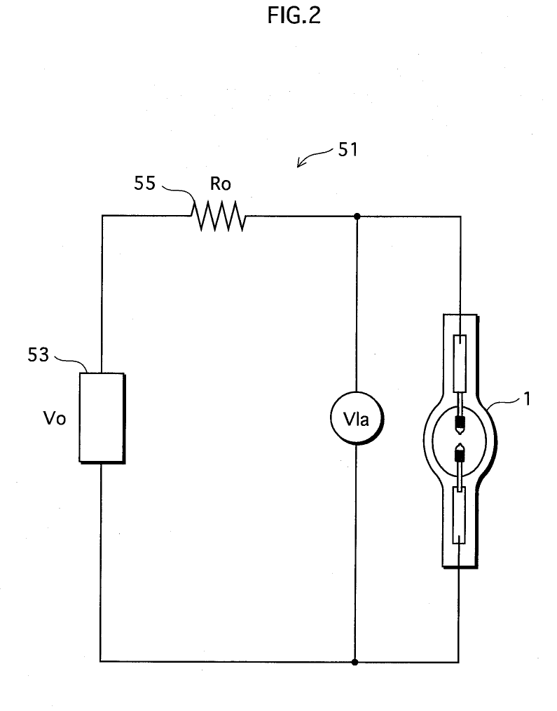

FIG. 2 is a conceptual drawing of the evaluation system.

In the present embodiment, the basic structure of the evaluation system is a device that includes a constant current supply unit 53 that supplies a constant current to the lamp 1, and a resistor 55 for restricting current. Although the evaluation system is described as an evaluation unit for this reason, the evaluation system may be, for instance, a system composed of mutually independent devices. Specifically the constant current supply unit 53 may be a constant current providing device that supplies constant current to the lamp 1, and the resistor 55 may be a resistor device comprising a current restricting resistor.

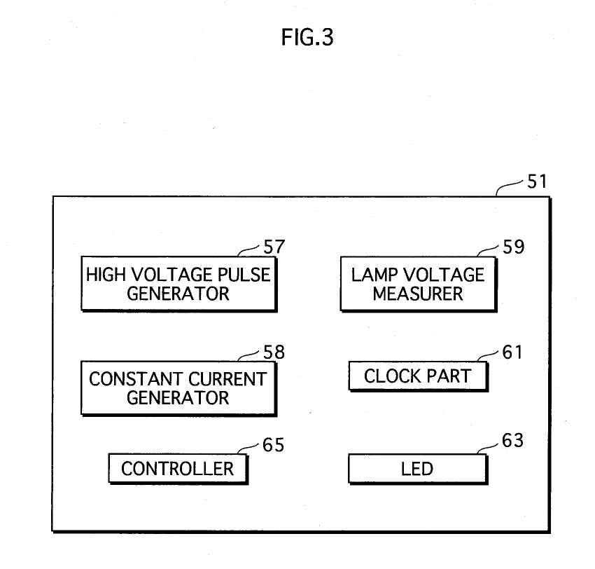

FIG. 3 is a block diagram of the evaluation unit of the present embodiment.

The evaluation unit 51 includes a high voltage pulse generator 57, a constant current generator 58, a lamp voltage measurer 59, a clock part 61, an LED (display part) 63 and a controller 65.

The high voltage pulse generator 57 generates a high pressure pulse that is applied to the lamp 1 while the lamp 1 is illuminated. Applying the high pressure pulse causes insulation breakdown to occur in the lamp 1, and the lamp 1 to start illumination.

After insulation breakdown has occurred in the lamp 1, the constant current generator 58 generates a constant current to cause the lamp 1 to illuminate with glow discharge in so-called cold cathode operation. The clock part 61 measures time elapsed since the insulation breakdown. Upon a predetermined amount of time elapsing after insulation breakdown occurs in the lamp 1, the lamp voltage measurer 59 measures the lamp voltage Vla during illumination in the glow discharge state.

The controller 65 issues instructions to illuminate the lamp 1, measure time and measure the lamp voltage Vla to the high voltage pulse generator 57, the constant current generator 58, the lamp voltage measurer 59 and the clock unit 61. The controller 65 also causes the LED 63 to light when the lamp voltage Vla measured by the lamp voltage measurer 59 is higher than a reference voltage Vref (when “the measured lamp voltage exceeds a pre-set reference voltage by a certain value or greater” in the present invention) that is a threshold value for the occurrence of blackening, in order to notify the user to such effect.

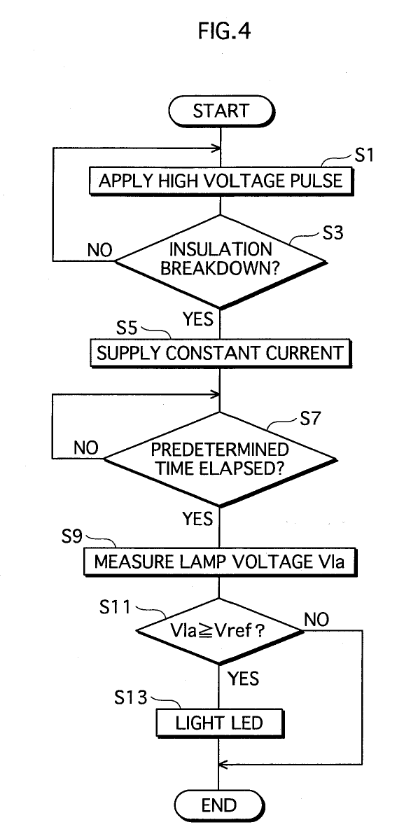

FIG. 4 is a flowchart pertaining to the controller.

The controller 65 instructs the high voltage pulse generator 57 to generate a high pressure pulse, and apply the high pressure pulse to the lamp 1 (S1). As a result, voltage begins to be applied to the lamp 1, and the controller 65 judges whether or not insulation breakdown has occurred in the lamp 1 (S3). Note that since the lamp 1 is put in an energized state as a result of the insulation breakdown, the judgement as to whether insulation breakdown has occurred is performed by detecting a drop in lamp voltage or the flow of lamp current.

At step S3, the controller 65 judges that the lamp 1 has not yet reached insulation breakdown if, for instance, a current of at least a predetermined value is not flowing through the lamp 1 (“NO” in FIG. 4). The controller 65 then returns to step 1 in this case. On the other hand, if current of at least the predetermined value is flowing, the controller 65 judges that insulation breakdown has occurred in the lamp 1 (“YES” in FIG. 4), causes the constant current generator 58 to generate constant current, and supplies the constant current to the lamp 1 (S5). The constant current causes the lamp 1 to illuminate according to the glow discharge in the cold cathode operation. At this time, the controller 65 instructs the clock unit 61 to measure time elapsed since the insulation breakdown.

Next, the controller 65 judges whether or not the predetermined amount of time has elapsed since the insulation breakdown (S7), and if the predetermined about of time has elapsed (“YES” in FIG. 4), instructs the lamp voltage measurer 59 to measure the lamp voltage Vla actually being applied to the lamp 1 (S9). Note that the lamp voltage Vla measured by the lamp voltage measurer 59 is output to the controller 65.

The controller 65 judges whether or not the lamp voltage Vla is equal to or greater than the reference voltage Vref (S11).

When the lamp voltage Vla is equal to or greater than the reference voltage Vref (specifically, when as a result of comparing the lamp voltage Vla and the reference voltage Vref, the lamp voltage Vla is found to be equal to or greater than the reference voltage Vref), the lamp 1 is evaluated has having a high possibility of blackening occurring, and the LED 63 is lit in order to notify the user that the possibility of blackening occurring is high (S13). The process then ends. On the other hand, when the lamp voltage Vla is lower than the reference voltage Vref (specifically, when as a result of comparing the lamp voltage Vla and the reference voltage Vref, the lamp voltage Vla is found to be lower than the reference voltage Vref), the gas state in the discharge space is evaluated as good. In other words, the lamp 1 is evaluated as having a relatively low amount of impure gas. The processing then ends without lighting the LED 63.

3. Test Results

The inventors researched methods that enable it to be judged relatively easily whether impurities remain in the discharge space 3 of the lamp 1, and whether or not the density of the impurities (or the amount of the impurities) is of an inappropriate level that will destroy the halogen cycle and cause blackening of the lamp 1 (i.e., whether the possibility of blackening occurring is high or low).

As a result of their research, the inventors found that by illuminating the lamp 1 in a manner that the lamp 1 performs discharge with a relatively low current, in other words, a glow discharge state in so-called cold cathode operation, the lamp voltage Vla at this time can be used to judge whether or not the density of impurities in the discharge space 3 of the lamp 1 is at an inappropriate level that will cause blackening.

The inventors also found that using this evaluation method enables lamps in which blackening is highly likely to be occur to be screened out in advance, and therefore in substance prevents lamps 1 that are on the market from having defects due to blackening.

A description is now given of lamp voltage and the occurrence of blackening when the lamp of the present embodiment illuminates with glow discharge.

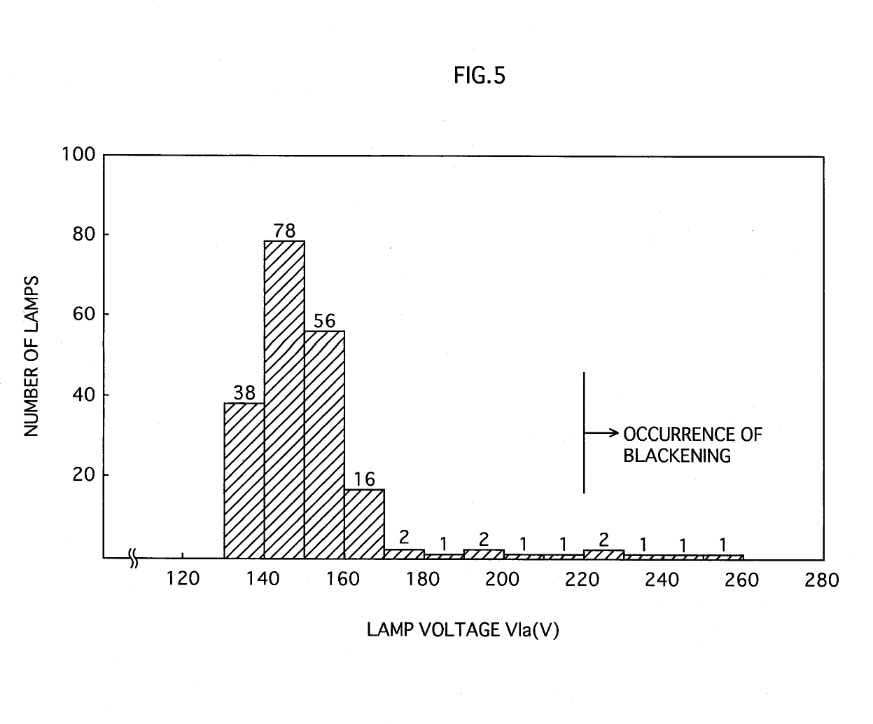

FIG. 5 shows distribution of lamp voltage in glow discharge.

The lamps (a plurality of the lamp 1) used in the test had the described specific example of structure, and were illuminated with 2.3 (mA) by the constant current supplier 53 shown in FIG. 2 and with 2.5 (MΩ) by the current restricting resistor 55 shown in FIG. 2. Note that the lamp voltage Vla was measured 90 seconds after insulation breakdown, and was measured in 200 lamps.

In FIG. 5, the horizontal axis represents lamp voltage, and the vertical axis represents the number of lamps that were within each of lamp voltage ranges. It can be seen from FIG. 5 that of the lamps 1 of which the lamp voltage Vla was measured, 188 lamps 1 had a lamp voltage Vla in a range from 130 (V) to under 170 (V), and 12 lamps 1 has a lamp voltage Vla of 170 (V) or higher.

Next, the lamps 1 of which the lamp voltage Vla was measured were subjected to a lighting ageing test for 1000 (hrs) in an arc discharge state (i.e., normal discharge), and the state of blackening of the lamps 1 was observed. Note that when the lamps 1 were illuminated in the arc discharge state, the lamp voltage Vla of all the lamps 1 was distributed in a narrow range of 55 (V) to 85 (V). A wide range of distribution of the lamp voltage Vla such as the range of 130 (V) to 260 (V) seen in illumination in the glow discharge state was not seen in the arc discharge state.

It is known that generally in the lamp 1 in which argon is filled at 10 (kPa) to 50 (kPa) simply as the noble gas for startup assistance and the distance De between electrodes is a relatively short 0.5 (mm) to 1.0 (mm), the lamp voltage Vla in the glow discharge state is distributed in a range of approximately 130 (V) to 160 (V). Therefore, it is assumed that in the lamps in which the lamp voltage Vla during lighting in the glow discharge state is a relatively high 170 (V) to 260 (V) (twelve of the lamps 1 as a result of the measurement), a significant amount of impurities remains in the discharge space 3.

The result of observing was that no blackening was found in the 188 lamps 1 that had a lamp voltage Vla of less than 170 (V), whereas occurrence of blackening was found after illumination even after a short lighting ageing time of 1 (hr) to 200 (hrs) in lamps having a lamp voltage of 170 (V) or higher, and in particular in five lamps 1 having a lamp voltage of 220 (V) or higher.

In the lamps used in the tests, the initial lamp voltage (i.e., the lamp voltage at shipping) was set at approximately 130 (V). In lamps in which blackening occurred in a short lamp ageing of 1 (hr) to 200 (hrs) after illumination, the lamp voltage Vla was 220 (V) or higher in the glow discharge state. As such, it can be seen that the possibility of blackening occurring is higher when the lamp voltage Vla in the glow discharge state is 90 (V) or higher than the value of the initial lamp voltage (130 (V)).

In other words, the results show that by screening out the lamps 1 that have a lamp voltage Vla of a value of 220 (V) or higher when illuminated in the glow discharge state, occurrence of blackening in the remaining lamps is substantially 100(%) avoided.

Accordingly, by performing the described evaluation test, for example, on the lamps 1 before shipping, lamps 1 having an inappropriate level of impurities can be screened out, and therefore lamps 1 that have a high possibility of blackening occurring can be prevented from entering into the market.

As has been described, as a result of carrying out various tests, the inventors found that the lamp voltage Vla measured during illumination in the glow discharge state is one type of physical parameter that shows the density of impurities in the lamp 1 (i.e., in the discharge envelope 3) relatively, and thus determined that it is possible to accurately judge whether the density of impurities in the lamp is an inappropriate level that will cause loss of the halogen cycle and therefore cause blackening of the discharge envelope.

The inventors also found that the reference voltage Vref, which is a physical parameter, can be found substantially accurately as being 220 (V) according to the described tests, and that lamps 1 having a lamp voltage higher than the reference voltage Vref can be screened out.

Furthermore, the evaluation unit pertaining to the present embodiment can be implemented easily with a simple structure, namely, measuring the lamp voltage Vla when the lamp is illuminated in a glow discharge state. In addition, the evaluation can be carried out not only for a lamp on its own, but also for a lamp that is already assembled into a lamp unit (described in the second embodiment).

### Second Embodiment

Whereas the evaluation unit 51 for the lamp 1 was described in the first embodiment, the second embodiment pertains to a projector that is an image display device having an illumination unit that includes a lamp as a light source. The projector includes a function of illuminating the lamp and a function of evaluating.

1. Projector

(1) Structure

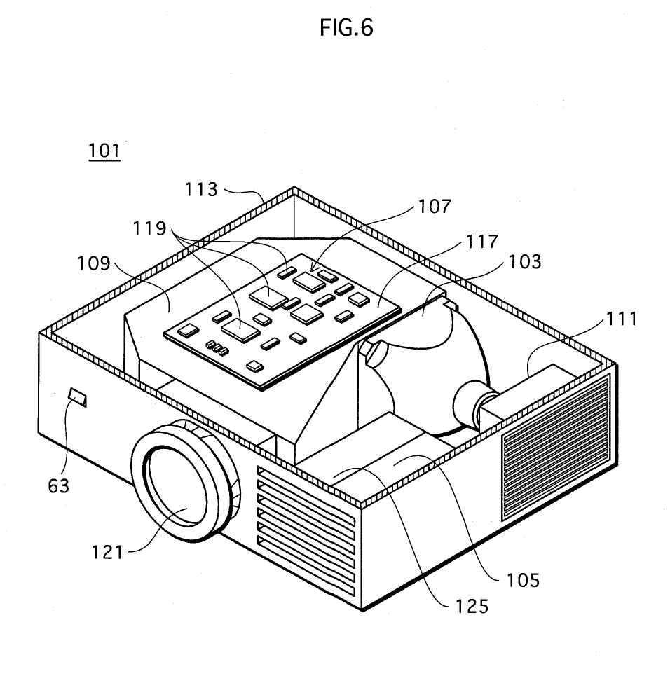

FIG. 6 is a perspective diagram of the projector of the present embodiment, with part of the projector cut away.

The projector 101 is a so-called forward projection type. As shown in FIG. 6, a case 113 of the projector 101 houses: a lamp unit 103 that includes a lamp therein; an illumination unit (125) that lights the lamp; a power unit 105 for supplying power to the various units and the like; a control unit 107; a lens unit 109 in which exists a lens system, a transmissive color liquid crystal display panel and the like; a fan device 111 for cooling the lamp; and so on. The lamp used in the present embodiment has a rated power of 120 (W), for instance.

In the present embodiment, the illumination unit 125 also has a function of evaluating the possibility of the occurrence of blackening of the lamp, and notifying a user or another party to replace the lamp.

The power unit 105 converts 100 (V)-household AC power to a predetermined voltage, and supplies the power of the predetermined voltage to the illumination unit 125, the control unit 107, and the like. The control unit 107 is composed of a substrate 117 disposed on a top part of the lens unit 109, and electronic and electrical components 119 and the like mounted on the substrate 117. The control unit 107 drives the color liquid crystal panel based on an image signal input from an external source, to display a color image. The control unit 107 also controls a driving motor provided inside the lens unit 109, in order to execute operations such as focusing and zooming.

Light emitted from the lamp unit 103 passes through the lens system provided in the lens unit 109, and is transmitted through the color liquid crystal display panel provided on the path of light. As a result, the image formed on the color liquid crystal display panel is projected via the lens 121 and the like onto a screen (not illustrated). Note that the lens unit 109 is provided such that part thereof juts out of case 113.

In addition to performing control such as control to illuminate the lamp and control to maintain the illuminated state, the illumination unit 125 also has functions of evaluating the possibility of blacking occurring in the lamp while the projector is being used, and when the possibility is high, lighting an LED 63 provided on a front surface of the case 113.

Note that the projector 101 performs an evaluation of the possibility of the occurrence of blackening during use of the lamp, and then lights the lamp in an arc discharge state to display images on the screen or the like (not illustrated).

(2) Circuit Structure

The illumination unit 125 is first described.

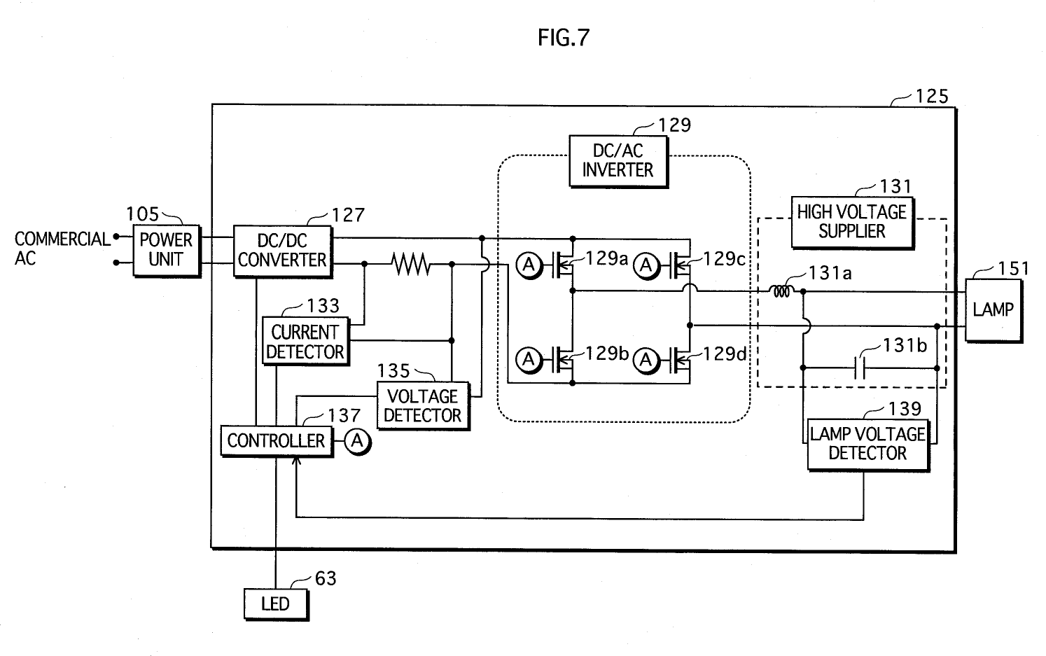

FIG. 7 is a block diagram of the illumination unit.

The illumination unit 125 receives direct current that results from conversion by the power unit 105, and causes the lamp 151 to illuminate in the arc discharge state after passing through the glow discharge state. The illumination unit 125 is composed of a DC/DC converter 127, a DC/AC inverter 129, a high voltage supplier 131, a current detector 133, a voltage detector 135, a controller 137, and a lamp voltage detector 139.

The DC/DC converter 127 converts direct current voltage supplied from the power unit 105 into direct current voltage of a predetermined voltage in accordance with a power setting signal from the controller 137 (described later), and supplies the predetermined direct current voltage to the DC/AC inverter 129.

The DC/AC inverter 129 includes, for instance, two pairs of switching elements (FETs), and by alternately turning the pairs of switching elements ON and OFF, applies a square wave alternating current of a predetermined frequency to the lamp 151. Note that the square wave alternating current is generated from direct current voltage provided from the DC/DC converter 127.

The high voltage supplier 131 generates high voltage by, for instance, using a resonating circuit that includes a coil 131a and a capacitor 131b. The lamp 151 receives the supply of the high voltage, and breaks insulation to start discharge.

The current detector 133 and the voltage detector 135 are directly connected to an input side of the DC/AC inverter 129, and indirectly detect the lamp current and the lamp voltage of the lamp 151 and send a resultant detection signal to the controller 137.

The controller 137 controls the direct current voltage value in the DC/DC converter 127 based on the detection results from the current detector 133 and the voltage detector 135. Note that the controller 137 has a lamp voltage-lamp power table, and controls such that illumination of the lamp 151 is maintained in accordance with conditions stipulated by this table.

Upon receiving a lamp voltage detection signal from the lamp voltage detector 139 that detects the lamp voltage in the glow discharge state after the lamp 151 has started operating, the controller 137 compares the detected lamp voltage Vla and the reference voltage Vref (here the reference voltage Vref is 300 (V) since the lamp 151 is illuminating in the glow discharge state using alternating current voltage), and lights the LED 63 if the lamp voltage Vla is higher than the reference voltage Vref. Note that as one example, the comparison of the reference voltage and the lamp voltage is performed using a comparator.

Next a description is given of the control by the controller 137.

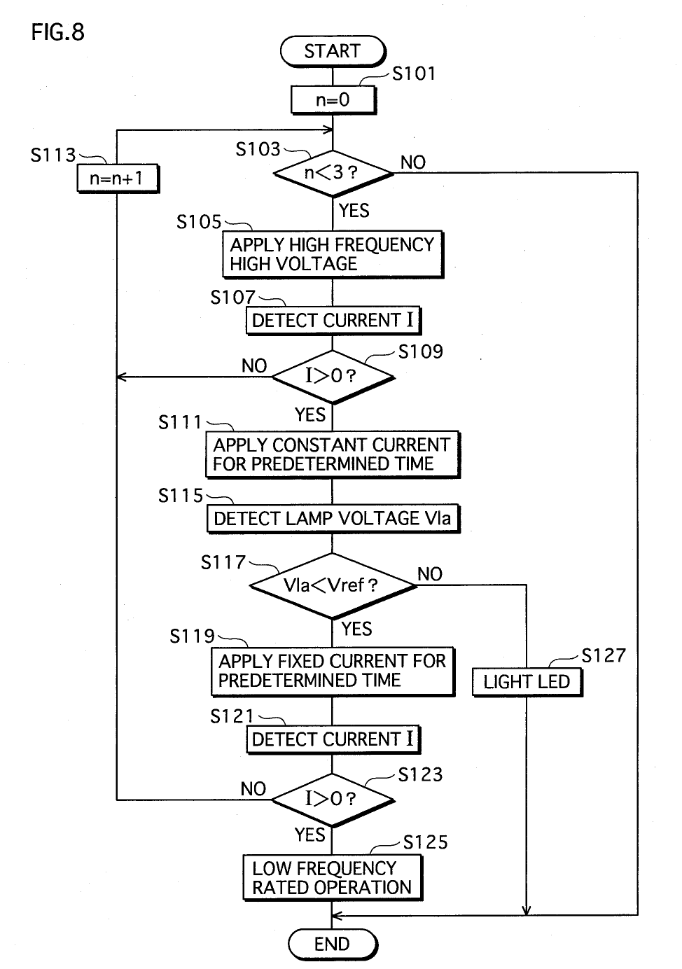

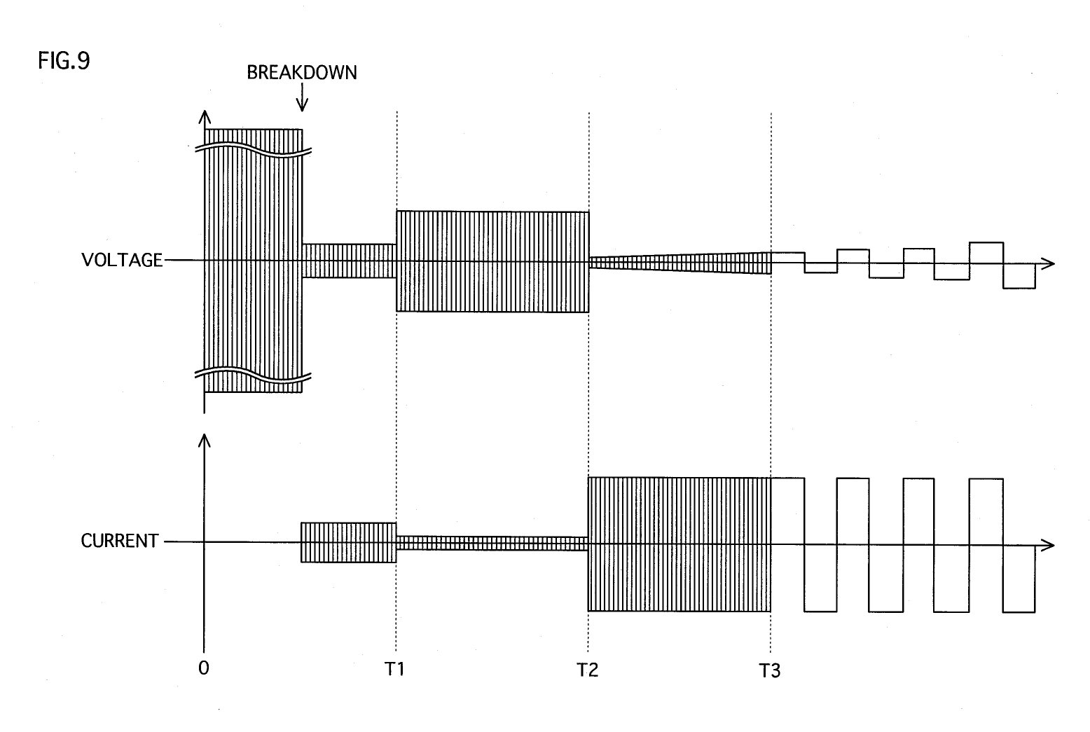

FIG. 8 is a flowchart pertaining to the control unit, and FIG. 9 shows lamp voltage and lamp current from when voltage starts to be applied to the lamp through to when arc discharge starts.

The controller 137 first sets a variable n, which shows how many times the lamp has been illuminated, to “0” (step S101), and judges whether the variable n is less than a predetermined number, for instance 3 (S103).

When the variable n is less than 3 (shown as “YES” in the drawing), the controller 137 applies a high frequency voltage to the lamp 151 for a predetermined about of time (S105). When the variable n is 3 (shown as “NO” in the drawing), this means that the lamp 151 cannot be illuminated (one reason may be that the lamp 151 has reached the end of its life), and therefore the controller 137 ends the control for illuminating the lamp 151.

In step S105, the high frequency voltage is applied by the high voltage supplier 131 for a period of time that lasts from 0 to T1 in FIG. 9. As one example, this high voltage has a frequency of 300 (kHz) to 600 (kHz) and a voltage value of 2 (kV) to 5 (kV).

As one example, the time T1 is one second (in other words, the interval from time 0 to time T1 is one second). Note that break down (insulation breakdown) in the lamp 151 occurs during the time 0 to the time T1, and then the high frequency high voltage is applied after the breakdown occurs, until the time T1 is reached.

When a predetermined time is reached after starting to apply the high frequency high voltage to the lamp 151 (i.e., when T1 is reached), the controller 137 detects current I via the current detector 133 (S107), and judges whether or not the current I is greater than 0 (S109).

When the current I is greater than 0 (shown as “YES” in the drawing; when breakdown has occurred in the lamp 151), the procedure advances to step S111, and the controller 137 applies a constant current for a predetermined amount of time in order to illuminate the lamp 151 in the glow discharge state. Furthermore, when the current I is 0 (shown as “NO” in the drawing; when breakdown has not occurred in the lamp 151), the controller 137 adds 1 to the variable n (S113) to apply high frequency high voltage to the lamp 151 again in order to start discharge, and returns to step S103.

Here, the current and voltage when constant current is applied at step S111 lasts from time T1 to time T2 in FIG. 9. The constant current has, for instance, a frequency of 100 (Hz) to 500 (kHz), and a current value of 0.1 (mA) to 3 (mA). Furthermore, while the constant current is applied, the frequency of the voltage is 100 (kHz) to 500 (kHz) and the voltage value is approximately 200 (V). The time T2 is two seconds (in other words, the interval from the time T1 to the time T2 is one second).

When the constant current has been applied at step S111 for the predetermined amount of time (time T1 to time T2), the controller 137 detects the lamp voltage Vla via the lamp voltage detector 139 (S115), and judges whether or not the detected lamp voltage Vla is lower than the reference voltage Vref (S117).

When the lamp voltage Vla is higher than the reference voltage Vref at step S117 (shown as “NO” in the drawing), the controller 137 evaluates the lamp 151 as having a high possibility of blackening occurring, and lights the LED 63 for a predetermined amount of time in order to notify the user of the high possibility of blackening (S127). The controller 137 then ends the control for lighting the lamp 151.

When, on the other hand, the lamp voltage Vla is lower than the reference voltage Vref (shown as “YES” in the drawing), the controller 137 evaluates the state of the gas in the discharge space of the lamp 151 as being good, in other words, the amount of impure gas as being small, and applies a fixed current for a predetermined amount of time (this fixed current is constant current having a constant current value, but is referred to as fixed current in order to distinguish from the constant current at step S111) in order to illuminate the lamp in the arc discharge state (S119). The controller 137 then detects the current I via the current detector 133 (S121), and judges whether or not the measured current I is greater than 0 (S123).

The current and voltage while the fixed current is applied are in the period shown as the time T2 to the time T3 in FIG. 9. The fixed current has, for instance, a frequency of 100 (kHz) to 200 (kHz) and a current value of 2 (A) to 4 (A). Furthermore, while the fixed current is applied, the frequency of the voltage is 100 (kHz) to 200 (kHz) and the voltage value is 10 (V) to 20 (V). The time T3 is three seconds (in other words, the interval from the time T2 to the time T3 is one second).

When current Ila at step S123 is greater than 0 (shown as “YES” in the drawing; when the lamp is sustaining illumination in the arc discharge state), the controller 137 causes the lamp to perform low frequency rated illumination (S125).

The low frequency rated illumination is performed by changing the cycle with which the switching elements 129a, 129b, 129c and 129d of the DC/AC inverter 129 are tuned ON and OFF to a low frequency.

Here, the current and the voltage during the low frequency rated illumination of step S125 are those at time T3 onwards in FIG. 9. As shown in FIG. 9, the current is a constant current until a steady state is reached, for instance with a frequency of 90 (Hz) to 500 (Hz) and a current value of 2 (A) to 6 (A). The frequency of the voltage is 90 (Hz) to 500 (Hz), and the lamp voltage is steadily increased (specifically, the lamp voltage is increased to substantially 70 (V)) until the lamp reaches the rated state (a lamp power of substantially 120 (W) in the present embodiment).

Note that the flowchart of the controller 137 is simply an example of an implementation in the second embodiment, and the present invention is not limited to the content of the flowchart.

For instance, instead of being the same as the current value of the fixed current in FIG. 9, the current value from the time T3 onwards may be higher than the current value of the fixed current (the period from time T2 to T3 in FIG. 9).

In other words, if the current when illuminating the lamp in the glow discharge state is said to be a first current (corresponding to the period from time T1 to time T2 in FIG. 9), the current when illuminating the lamp in the arc discharge state is said to be a second current (corresponding to the period from time T2 to time T3 in FIG. 9), and the current when illuminating the lamp so as to be in the rated state (corresponding to the time T3 onwards in FIG. 9) is said to be a third current, the current value of the second and third currents may be the same or may be different.

2. Lamp Unit

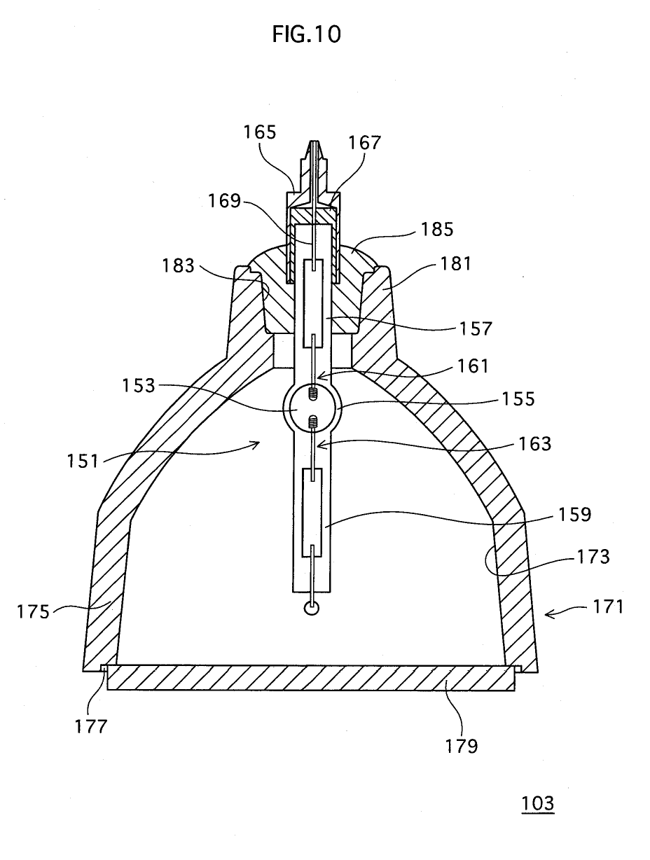

FIG. 10 is a vertical cross sectional view of the lamp unit of the second embodiment.

As shown in FIG. 10, the lamp unit 103 includes the lamp 151 and a reflecting mirror 171, with the lamp 151 being provided inside the reflecting mirror 171.

The lamp 151 has the same structure as the lamp 1 shown in FIG. 1, but is slightly more elongated since the power applied to the lamp 151 is different to the lamp 1 of the first embodiment.

The lamp 151 is composed of a discharge envelope 155 having an internal discharge space 153, and electrode structures 161 and 163 that are sealed through sealing portions 157 and 159 such that a tip of the electrode structures 161 and a tip of the electrode structure 163 oppose each other in the discharge space 153.

Furthermore, a base 165 is attached to the sealing portion 157 via cement 167, and an external lead wire 169 is connected to the base 165.

As shown in FIG. 8, the reflecting mirror 171 has a main body member 175 in which a concave reflecting surface 173 is formed. A front glass panel 179 is provided at an opening 177 of the main body member 175. Note that as one example, the main body member 175 and the front glass panel 179 are fixed to each other using a silicone adhesive agent.

The reflective mirror 171 is, for instance, a dichroic mirror, and reflects light emitted from the lamp, in a predetermined direction (towards the front glass panel 179). The main body member 175 is funnel shaped, and a through hole 183 is provided in a small diameter portion 181 (the portion where the outer diameter is small). The sealing portion 157 of the lamp 151 is inserted through the through hole 183.

The lamp 151 is installed in the reflective lamp 171 by, as shown in FIG. 10, inserting the sealing portion 157 to which the base 165 is attached a predetermined amount through the through hole 183 in the small diameter portion 181 of the main body member 175, and with the lamp in this state, fixing the lamp 171 using cement 185, for instance.

The projector 101 having the described structure also includes an evaluation unit (equivalent to the evaluation system of the present invention) 115 that is identical to the evaluation unit of the first embodiment. Therefore, the projector 101 is able to notify the user when the possibility of blackening occurring in the lamp 151 in the projector 101 increases and the time to replace the lamp 151 is approaching.

Furthermore, when the lamp 151 has been subjected to considerable illumination (i.e., has been subjected to relatively long lighting ageing), impurities separate out from the discharge envelope 155. Such impurities can all be used to evaluate the possibility of blackening occurring.

<Other>

1. Regarding Illumination in the Glow Discharge State

In the first embodiment, the illumination conditions for glow discharge were stated as being as follows: a constant current of 2.3 (mA), the resistor 55 for restricting current being 2.5 (MΩ), and the voltage during constant current supply being DC 6 (kV). However, other illumination conditions are possible as long as the lamp can be illuminated in a glow discharge state.

For instance, the voltage during constant current supply may be any voltage in a range in which startup of the lamp is possible, such as a range of 0.1 (kV) to 20 (kV), and the power supplied may be either direct current or alternating current.

Furthermore, the resistor 55 for restricting direct current may be in a range of 200 (kΩ) to 40 (MΩ), and this will cause the lamp to illuminate in the glow discharge state after startup according to a relatively low lamp current, for instance 150 (μA) to 30 (mA).

Furthermore, although the lamp voltage Vla during illumination in the glow discharge state was described as being measured approximately 90 seconds after insulation breakdown, the timing with which the lamp voltage Vla is measured is not limited to being 90 seconds. The lamp voltage Vla may be measured whenever glow discharge is in a stable state after insulation breakdown, and the time at which the lamp voltage Vla is measured may be determined appropriately for the illumination conditions. However, in such a case it will be necessary to set a new reference voltage, and this will potentially lower the accuracy with which satisfactory products can be distinguished from faulty products slightly.

2. Regarding the Reference Voltage Vref

In the first embodiment, the reference voltage for the 120 W direct current lamp 1 is 220 (V), and in the second embodiment the reference voltage for the alternating current lamp, which is also 120 W type, is 300 (V).

In other words, even for lamps having the same specifications, the reference voltage will be different depending on the type of voltage supplied when illuminating the lamp in the glow discharge state. However, if the supplied voltage is the same type, the present invention can be applied to lamps to which the power applied is a power other than 120 (W).

In such a case, strictly speaking it is necessary to experiment to find the reference voltage Vref for each type of lamp. However, as described in the section “3. Test Results” in the first embodiment, in a lamp in which only argon is enclosed in the lamp 1 and the distance De between electrodes is similarly relatively short, even if the power applied to the lamp is not 120 (W), the lamp voltage Vla during illumination in a glow discharge state using direct current (i.e., the initial lamp voltage Vla) is distributed in a range of 130 (V) to 160 (V). It is thought that even if the lamp is a lamp other than the type that has an applied power of 120 (W), the lamp voltage Vla at an initial stage will be the same level as in a lamp that has an applied type of 120 (W), and therefore the reference voltage Vref can be set at approximately 220 (V).

Therefore, the value when “the measured lamp voltage exceeds a pre-set reference voltage by a certain value or greater” in the present invention should be considered to be a value (220 (V)) that is 90 (V) higher than the initial lamp voltage when the voltage with which the lamp is illuminated in the glow discharge state is direct current voltage. Similarly, in the case of the voltage with which the lamp is illuminated in the glow discharge state is alternating current, the value when “the measured lamp voltage exceeds a pre-set reference voltage by a certain value or greater” in the present invention should be considered to be a value (300 (V)) that is 60 (V) higher than the initial lamp voltage (240 (V)) when the voltage with which the lamp is illuminated in the glow discharge state.

3. Regarding a Certain Value with Respect to the Reference Value

In the embodiment, “the measured lamp voltage exceeds a pre-set reference voltage by a certain value or greater” is used to mean “the measured value being at least 90 (V) higher than the initial lamp voltage value in the case of the voltage supplied to illuminate the lamp in the glow discharge state being direct current voltage”. However, a certain value or greater may mean “50 (V) or higher” or “a value in a range of 50 (V) to 90 (V), or higher”.

In this case, if the certain value is set as 90 (V), evaluation can be performed using a reference for a case of there being an extremely high possibility of the lamp being faulty. On the other hand, if the certain value is set as 50 (V), this will mean that evaluation is performed using a reference for which the possibility of the lamp being faulty is lower than when the certain value is 90 (V).

In this way, when the certain value is set to be (i) 50 (V) or higher or (ii) in a range of 50 (V) to 90 (V), lamps having a possibility of problems occurring can be widely detected. This enables the occurrence of problems in lamps to be reliably suppressed, thus reducing the possibility of problems occurring, and providing high quality lamps. This can also be said for a certain value (60 (V)) in the case of alternating current voltage.

Here, the reason the certain value is set at 50 (V) is that the rate of occurrence of lamp problems can be made extremely low, and also because if the certain value was lower than 50 (V), normal lamps would also be evaluated as having a high possibility of problems occurring. This can also be said for a certain value (60 (V)) in the case of alternating current voltage.

4. Evaluation Unit (Evaluation System)

Although the evaluation unit is included in the projector as an illumination unit having an evaluation function in the second embodiment, the illumination unit (illumination device) can be used as a lighting apparatus for a general lighting.

5. Regarding Lamp Driving

In the second embodiment, the lamp 151 is driven in the glow discharge state by a circuit for illuminating (driving) the lamp 151, the circuit being included in the illumination unit 201 that causes the lamp 151 to illuminate. However, instead the lamp may be driven using another driving circuit, and abnormalities or faults in the lamp may be evaluated in the controller of the illumination unit.

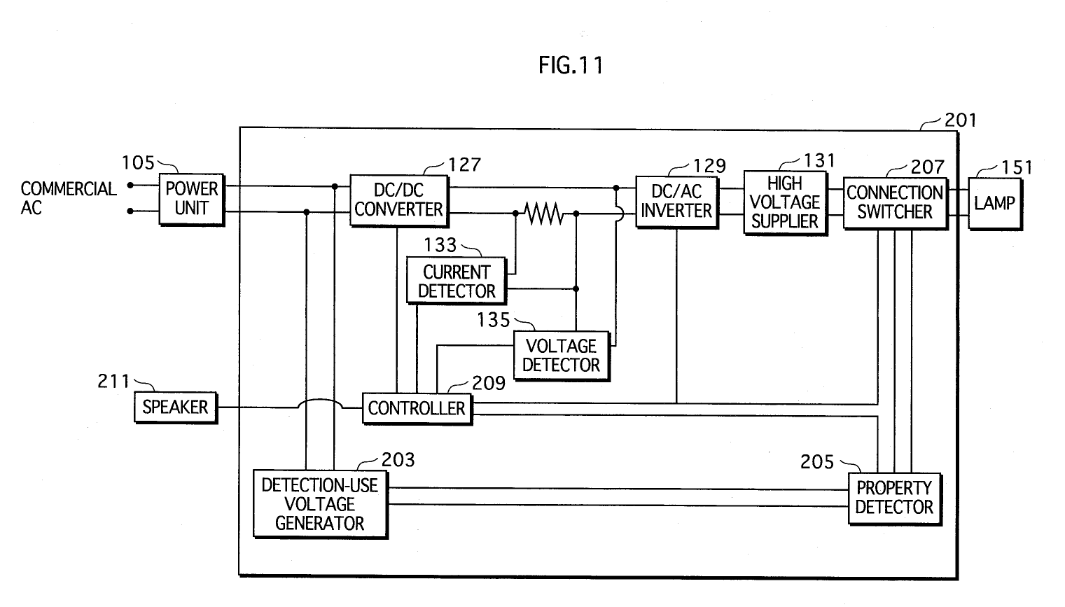

FIG. 11 is a block diagram of an illumination unit that is an example of a modification to the second embodiment.

The illumination unit 201 includes a DC/DC converter 127, a DC/AC inverter 129, a high voltage supplier 131, a current detector 133, a voltage detector 135, a detection-use voltage generator 203, a property detector 205, a connection switcher 207 and a controller 209.

The DC/DC converter 127, the DC/AC inverter 129, the high voltage supplier 131, the current detector 133, the voltage detector 135 and the lamp 151 are the same as in the second embodiment, and therefore a description thereof is omitted here.

The detection-use voltage generator 203 generates voltage for causing the lamp 151 to illuminate in the glow discharge state. The property detector 205 detects lamp voltage and/or lamp current being applied to the lamp 151, and sends the detected lamp voltage and/or lamp current to the controller 209.

The connection switcher 207 connects the high voltage supplier 131 and the detection-use voltage generator 203 to the lamp 151. In accordance with an instruction from the controller 209, the connection switcher 207 switches between voltage supplied to the lamp 151 from the high voltage supplier 131 and voltage supplied to the lamp 151 from the detection-use voltage generator 203.

Specifically, the connection switcher 207 connects the high voltage supplier 131 to the lamp 151 when, for instance, the lamp 151 is being illuminated or the illumination is being maintained, and the connection switcher 207 connects the detection-use voltage generator 203 to the lamp 151 when detection of abnormalities and faults in the lamp 151 are being detected for. Note that the detection-use voltage generator 203 is connected to the connection switcher 207 via the detector 205.

The controller 209 controls the DC voltage value in the DC/DC converter 127 based on detection results from the current detector 133 and the voltage detector 135. In addition, upon receiving a lamp voltage detection signal from the property detector 205 that detects the lamp voltage in the glow discharge state after the lamp 151 is started up, the controller 209 compares the lamp voltage Vla with the reference voltage Vref described in the first embodiment, and when the lamp voltage Vla is higher than the reference voltage Vref, has the speaker 211 emit a warning sound as external output.

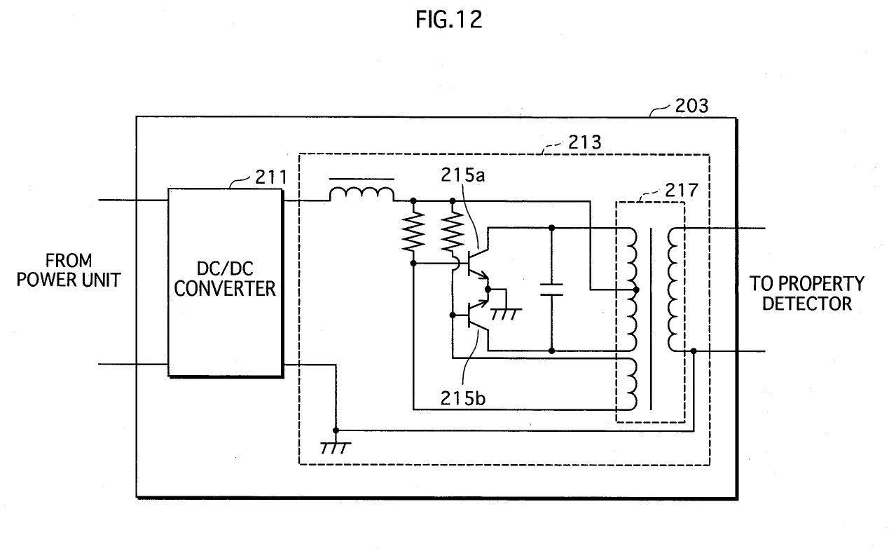

FIG. 12 is a circuit diagram of the detection-use voltage generator.

The detection-use voltage generator 203, as shown in FIG. 12, includes a DC/DC converter 211 at a first stage, and a collector resonant-type inverter circuit 213.

The collector resonant-type inverter circuit 213 is composed of two switching elements 215a and 215b, a transistor 217, and so on. DC power output from the DC/DC converter 211 causes AC current in a secondary winding side in accordance with the two switching elements 215a and 215b being turned ON and OFF.

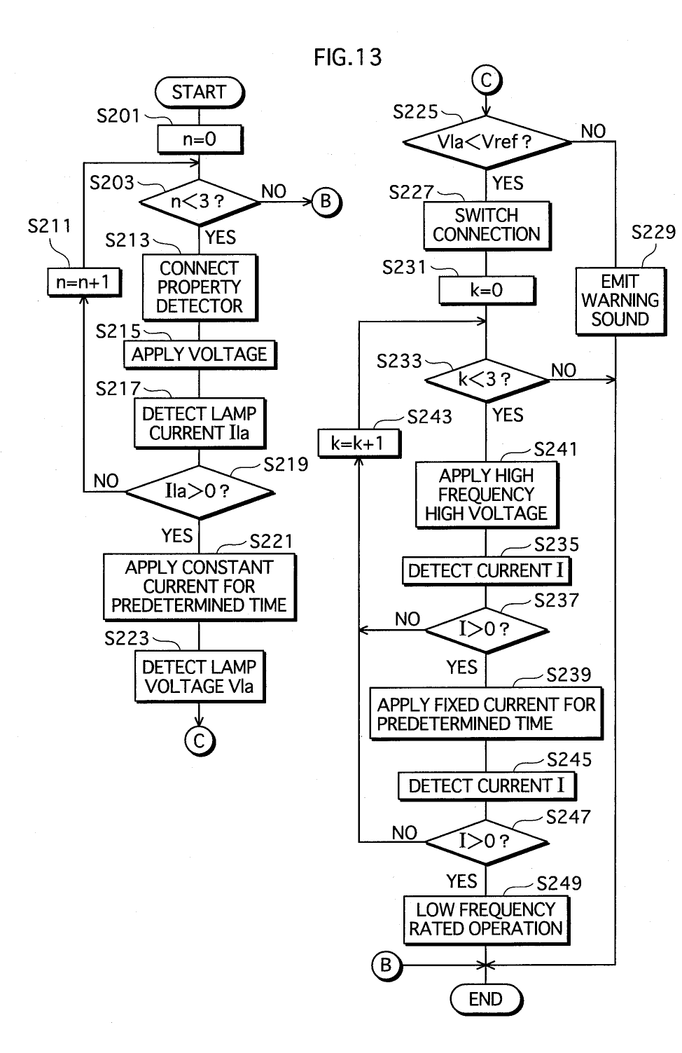

FIG. 13 is a flowchart pertaining to the controller of the illumination unit that is an example of a modification of the second embodiment.

The controller 209 first sets “0” in a variable n that expresses how many times the lamp 151 has been illuminated (S201), and judges whether or not the variable n is less than a predetermined number, for instance 3 (step S203).

When the variable n is less than 3 (YES in the drawing), the controller 209 instructs the connection switcher 207 to connect the property detector 205 to the lamp 151, in order to have the lamp 151 illuminate in the glow discharge state (S213), and applies voltage to the lamp 151 to cause breakdown to occur (S215).

Then, the controller 209 detects the lamp current Ila by way of the property detector 205 (S217), and judges whether the lamp current Ila is greater than 0 (S219).

On the other hand, when the variable n is 3 at step S203 (NO in the drawing), the lamp 151 is in a state in which it cannot be illuminated (e.g., because the lamp 151 has reached the end of its life), and therefore the controller 209 ends the control for illuminating the lamp 151.

When the lamp Ila is greater than 0 at step S219 (shown as “YES” in the drawing), in other words, when breakdown has occurred and current is flowing in the lamp 151, the procedure advances to step S221, and the controller 209 applies a constant current for a predetermined amount of time in order to illuminate the lamp 151 in the glow discharge state. When, on the other hand, the lamp current Ila is 0 at step S219 (shown as “NO” in the drawing), in other words, when breakdown has not occurred, the controller 209 adds 1 to the variable n (S211) to again cause breakdown in the lamp 151, and returns to step S203.

Note that the conditions for applying the constant current at step S221 are the same as the conditions at step S111 in FIG. 8 in the second embodiment.

When the constant current has been applied for a predetermined amount of time at step S221, the lamp voltage Vla is measured (S223), and the controller 209 judges whether or not the measured lamp voltage Vla is lower than the reference voltage Vref (S225).

At step S225, when the lamp voltage Vla is lower than the reference voltage Vref (shown as “YES” in the drawings), the controller 209 evaluates the state of the gas in the discharge space of the lamp 151 as being good, in other words, the amount of impure gas as being small, and proceeds to the steps for normal illumination of the lamp 151 (S227 onwards). When the lamp voltage Vla is greater than the reference voltage Vref (shown as “NO” in the drawing), the lamp 151 is evaluated has having a high possibility of blackening occurring, and a warning sound is emitted in order to notify the user that the possibility of blackening occurring is high (S229). The control to illuminate the lamp 151 then ends.

In the control for normal illumination of the lamp 151, the controller 209 first switches the connection to the lamp 151 from the property detector 205 to the high voltage supplier 131 (S227), sets a variable k representing the number of times the lamp has been illuminated to 0 (S231), and judges whether or not the variable k is less than 3 (S233).

When the variable k is less than 3 (shown as “YES” in the drawing), the controller 209 applies a high frequency high voltage to the lamp 151 to cause breakdown in the lamp (S241), measures the current I by way of the current detector 133 (S235), and judges whether or not the current I is greater than 0 (S237).

When the current I is greater than 0 at step S237 (shown as “YES” in the drawing), in other words, when the lamp 151 is in a discharge state, the controller 209 proceeds to step S239, and applies a fixed current for a predetermined amount of time in order to illuminate the lamp 151 in the arc discharge state.

On the other hand, when the current I is 0 at step S237 (shown as “NO” in the figure), in other words when the lamp 151 is not in a discharge state, the controller 209 adds 1 to the variable k (S243) to again cause breakdown in the lamp 151. The controller 209 then returns to step S233.

Note that the conditions for applying the high frequency high voltage to the lamp at step S241 are the same as the conditions at step S105 of FIG. 8 in the second embodiment, and the conditions for applying the fixed current for the predetermined amount of time at step S239 are the same as the conditions at 5119 of FIG. 8.

When the fixed current has finished being applied for the predetermined time at step S239, the controller 209 measures the current I (S245), and judges whether or not the measured current I is greater than 0 (S247).

When the current I is greater than 0 at step S247 (in other words, when the lamp 151 is maintaining illumination in the arc discharge state; shown as “YES” in the figure), the lamp 151 performs the same low frequency rated illumination as the low frequency rated operation at step S125 FIG. 8 (S249).

On the other hand, when the current I is 0 at S247 (shown as “NO” in the figure), in other words when the lamp 151 is not in a discharge state, the controller 209 adds “1” to the variable k (step 243) in order to again cause breakdown in the lamp 151, and returns 25, to step S233.

Note that although the detection-use voltage generator in the present modification example is structured so as to apply AC voltage to the lamp 151 as described with respect to FIG. 12, the detection-use voltage generator may instead be structured to apply DC voltage as in the first embodiment.

6. Image Display Device

Although the projector in the second embodiment is described as being a front panel projection type in the second embodiment, the projector may be another type such as a back panel projection type.

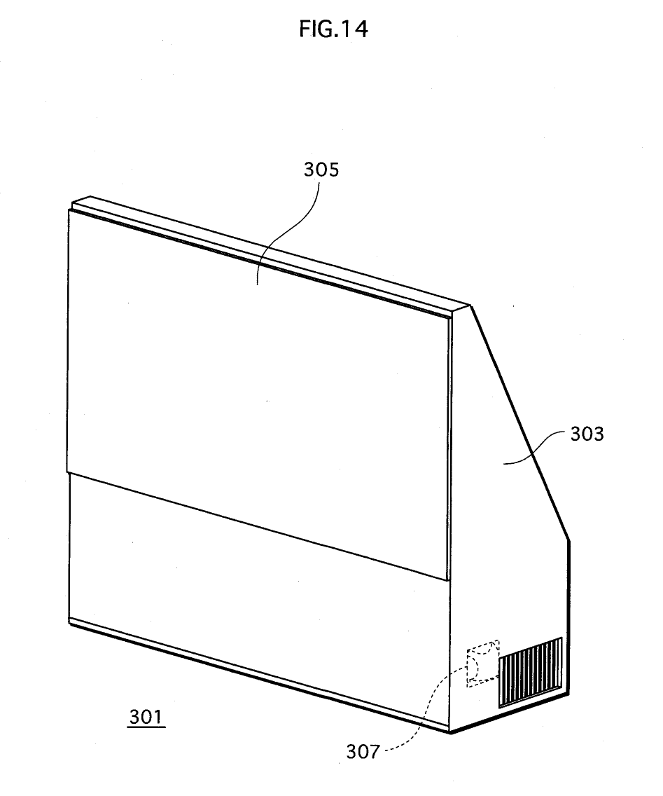

FIG. 14 is an overall perspective view of a back panel projection type image display device.

A back panel projection type projector 301 includes a screen 305 for displaying images and the like on a front wall of a cabinet 303. A lamp unit 307 and an evaluation unit are provided as separate entities inside the cabinet 303.

7. Lamp

Although a high pressure mercury discharge lamp is described in the embodiments and the modification example, the present invention can also be applied to evaluation of the state of existence of molecular gas in low pressure discharge lamps such as a cold cathode fluorescent lamps and hot cathode fluorescent lamps having mercury as an ultraviolet light emitting matter.

8. Other

Although respective embodiments and modifications have been described, it is possible to combine embodiments with each other or combine modification examples with each other. It is also possible to combine one or more embodiments with one or more modification examples. Note that the specific examples given in each of the embodiments and modification examples are simply one example of the present invention, and do not limit the embodiments or modification examples.

### INDUSTRIAL APPLICABILITY

The present invention can be used in an evaluation system, an illumination device and an image display device having an evaluation function capable of easily evaluating the state of gas in a discharge space.

1. An evaluation system for evaluating a state of existence of molecular gas in a discharge space in a discharge lamp, the evaluation system comprising:
an illumination unit operable to cause the discharge lamp to illuminate in a normal glow discharge state;
a voltage measuring unit operable to measure lamp voltage of the discharge lamp illuminated in the normal glow discharge state;
an evaluation unit operable to make an evaluation that the measured lamp voltage exceeds a pre-set reference voltage by a certain value or greater; and
an output unit operable to output a result of the evaluation.

2. The evaluation system of claim 1, wherein
the discharge lamp is a high pressure discharge lamp, and mercury, halogen and argon are contained in the discharge space,
the illumination unit causes the high pressure discharge lamp to illuminate in the normal glow discharge using a lamp current that is a direct current,
the pre-set reference voltage is an initial lamp voltage value, and
the certain value is 90 V.

3. The evaluation system of claim 1, wherein
the discharge lamp is a high-pressure discharge lamp, and mercury, halogen and argon are contained in the discharge space,
the illumination unit causes the high pressure discharge lamp to illuminate in the normal glow discharge using a lamp current that is an alternating current,
the pre-set reference voltage is an initial lamp voltage value, and
the certain value is 60 V.

4. An illumination device for illuminating a discharge lamp in which a pair of electrodes are provided in a discharge envelope and mercury is contained in a discharge space, the mercury being a light emitting matter or an ultraviolet light emitting matter, the illumination device including:
an evaluation unit operable to evaluate a state of existence of molecular gas in a discharge space in a discharge lamp,
wherein the evaluation unit is the evaluation system of claim 1.

5. An image display device including a discharge lamp in which a pair of electrodes are provided in a discharge envelope and mercury is contained in a discharge space, the mercury being a light emitting matter or an ultraviolet light emitting matter, the image display device including:
an evaluation unit operable to evaluate a state of existence of molecular gas in a discharge space in a discharge lamp,
wherein the evaluation unit is the evaluation system of claim 1.
